(19) United States
(12) Patent Application Publication
(10) Pub. No.: US 2008/0267428 A1
(43) Pub. Date: Oct. 30, 2008

(54) Digital audio horn

(75) Inventors: Thomas Pilette, Lake Orion, MI (US); Kimberly Knapp, Windsor (CA); Anthony J. Povinelli, Romeo, MI (US)

Correspondence Address: WARN, HOFFMANN, MILLER & LALONE, .P.C, PO BOX 70098, ROCHESTER HILLS, MI, 48307, US

(73) Assignee: Magna International Inc., Aurora (CA)

(21) Appl. No.: 11/789,357

(22) Filed: Apr. 24, 2007

(51) Int. Cl. H03F 21/00

(52) U.S. Cl. 381/120

(57) ABSTRACT

A device for producing sound amplification having a control module operably associated with a digital sound device, and an amplifier connected to and supporting the digital sound device. The control module provides at least one input signal to the digital sound device, and the digital sound device receives an input signal from the control module, causing the digital sound device to produce a vibration, and causing the amplifier to increase the magnitude of the vibration.

### FIELD OF THE INVENTION

The present invention relates to horns for motor vehicles, and other applications. More specifically, the present invention is a digital horn device which is used for motor vehicles.

### BACKGROUND OF THE INVENTION

Currently, almost all horns used for automotive applications are electromechanical. In order to perform as desired, various design parameters are imposed on these various horns. These parameters include specific locations, orientation, mounting and tuning configurations and techniques. In addition, every horn is designed and/or tuned to produce a specific note. As such, horns must be individually designed and/or tuned to produce different notes when used in different applications or locations in a vehicle. Conventional horns for automotive applications are also bulky, and draw a significant amount of power from the vehicle battery.

The current design of horns used in automotive applications limits the flexibility and increases costs in a variety of ways. First, every horn can only produce one note, or chord. The note of a horn is determined by many factors, including the flexibility of the horn's diaphragm, physical size, the power of the electromagnet, mass of the diaphragm, mechanical arrangement of the switch contact, the size and shape of the horn's case, and a number of other contributing factors. Because different types of vehicles have different horn frequency requirements, the same horn cannot be used for every vehicle produced. Even assuming that it is possible to use a single horn design in more than one application, each application requires tuning at a specific mounting location in a vehicle.

There are also strict guidelines as to the location of where a horn can be placed in the vehicle, in order to maintain functionality and reliability. The trumpet must be oriented so as to avoid water accumulation or solid projections (gravel, dirt, etc.) in the trumpet. In some cases, baffle plates or shields must be installed for protection. Also, a minimum distance from the trumpet's mouth to other components must be maintained to avoid attenuating the sound. Specific locations in the front end of the vehicle are typically recommended to produce a clear sound.

There are also specific mounting conditions recommended for electromechanical horns to maintain sound integrity. The horn must be mounted to a bracket with a specific elasticity along the main axis. There must also be a minimum amount of contact area between the bracket and a planar (minimum concavity typically given) mounting surface.

Thus, it is a goal in the art to cure one or more of the deficiencies in the art which are noted above.

### SUMMARY OF THE INVENTION

The present invention is a device for producing sound amplification having a control module operably associated with a digital sound device, and an amplifier connected to and supporting the digital sound device. The control module provides at least one input signal to the digital sound device, and the digital sound device receives an input signal from the control module, causing the digital sound device to produce a vibration, and causing the amplifier to increase the magnitude of the vibration.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a perspective view of a digital audio horn device, according to the present invention;

FIG. 2 is a first sectional view of an alternate embodiment of a digital audio horn device, according to the present invention;

FIG. 3 is a second sectional view of an alternate embodiment of a digital audio horn device, according to the present invention;

FIG. 4 is a perspective view of a second alternate embodiment of a digital audio horn device, according to the present invention;

FIG. 5 is a first sectional view of a second alternate embodiment of a digital audio horn device, according to the present invention; and

FIG. 6 is a second sectional view of a second alternate embodiment of a digital audio horn device, according to the present invention.

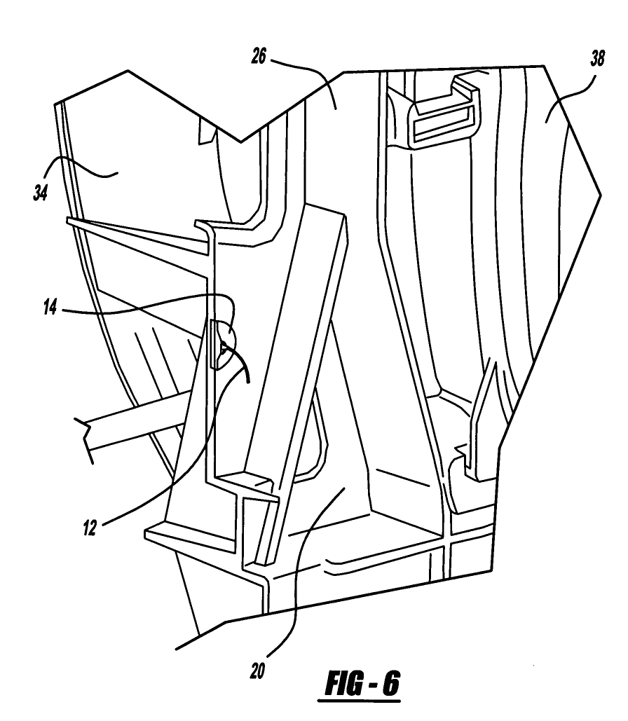

### DETAILED DESCRIPTION OF THE PREFERRED EMBODIMENTS

The following description of the preferred embodiment(s) is merely exemplary in nature and is in no way intended to limit the invention, its application, or uses.

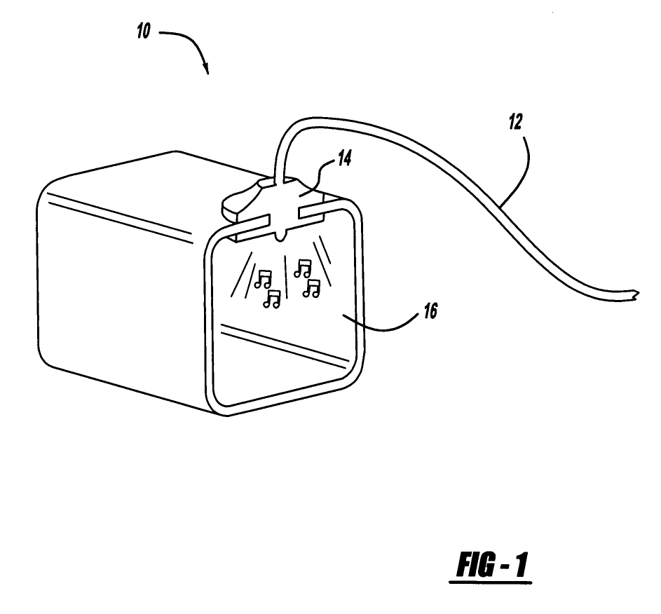

A digital audio horn device is generally shown in FIG. 1 at 10. The digital audio horn 10 also has a control module (not shown), which can be in the form of a power module, referred to as a TIPM (totally integrated power module). The power module provides the power and also has the ability to send a control signal to create a note. The control signal can be digital input in the form of a digital audio signal. Digital input is specific to the desired output (note). The power module is connected to a connector, which in this embodiment is a power feed 12, which is used for transmitting the digital audio signal from the power module to a digital sound device 14. The digital sound device 14 is, in this embodiment, in the form of a digital to analog converter. The digital sound device 14 converts a digital audio signal (stream of numbers) to an analog wave. The digital sound device 14 runs at a specific sampling rate and bit resolution through the process of over sampling, unsampling, and down sampling. The digital sound device is mounted to an amplifier 16. The amplifier 16 amplifies the analog wave produced by the digital sound device 14. An existing vehicle component can function as the amplifier 16. For example, a fender or the hood, or another existing vehicle component can serve as the amplifier 16, amplifying the analog wave to produce the desired sound.

In operation, the control module provides the power and control signal to create a note to the digital sound device 14 through the use of the power feed 12. As the signal is delivered to the digital sound device 14, the signal is converted from a digital audio signal to an analog wave. Once the digital sound device 14 has converted the digital audio signal to an analog wave, the amplifier 16 amplifies the analog wave and produces the desired output note.

Specific embodiments of the invention are shown in the Figures. In FIG. 1, the amplifier 16 is a cross-member 16 of the vehicle frame of an automobile. The digital sound device 14 is connected to the cross-member 16.

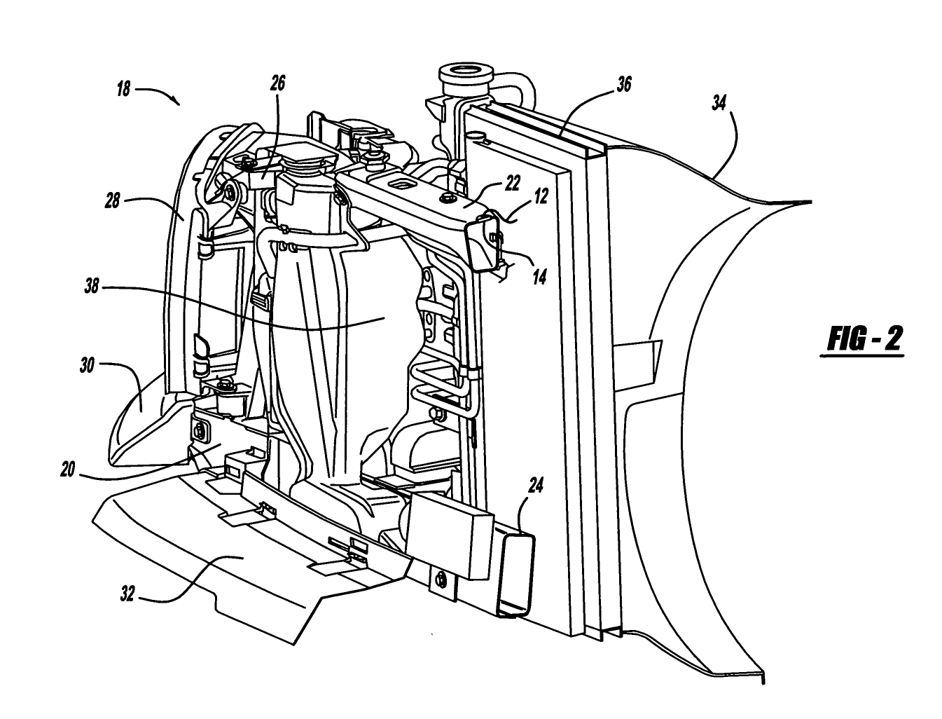

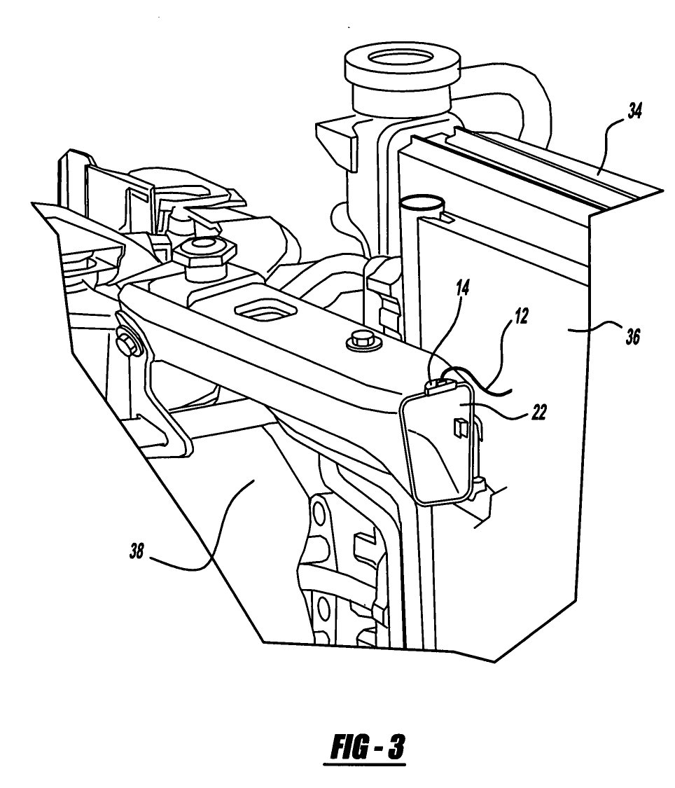

Referring now to FIGS. 2 and 3, a portion of a front end module is generally shown at 18. The front end module 18 has various components that are used in an automobile. The front end module 18 has a carrier 20 for supporting various vehicle components. The carrier 20 has an upper cross-member 22, a lower cross-member 24, and lamp supports 26 for supporting a headlamp 28. The carrier 20 also includes at least one support member 30 and a center support 32 which are used for supporting a top cap or front fascia (not shown). Also included are a fan shroud 34, a radiator 36, and a container 38 for holding coolant that flows through the radiator 36.

In this embodiment, the digital sound device 14 is connected to the upper cross-member 22, and the upper cross-member 22 serves as the amplifier 16. As the control signal, typically in the form of a digital audio signal, is delivered to the digital sound device 14, the digital sound device converts the digital audio signal into an analog wave, which is then amplified by the amplifier 16, which in this embodiment is the upper cross-member 22.

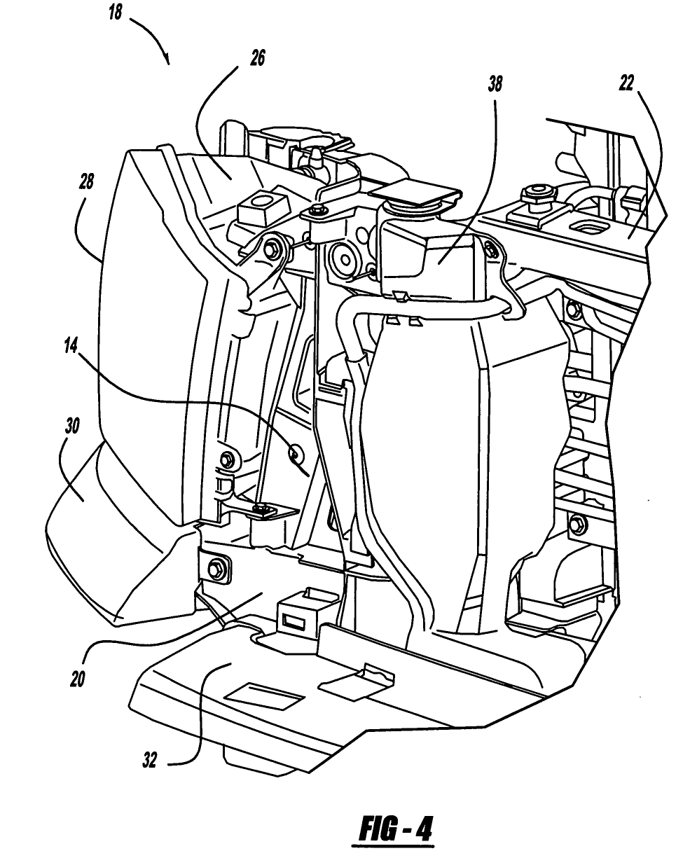

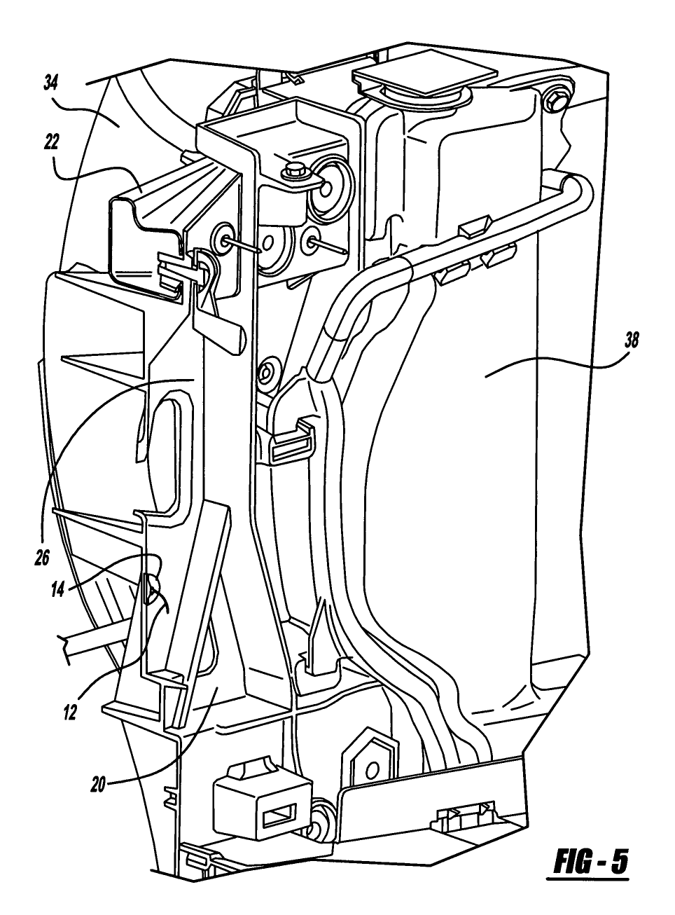

Another embodiment of the present invention is shown in FIGS. 3-5. In this embodiment, the digital sound device 14 is connected to one of the lamp supports 26 of the carrier 20. A sectional view of the digital sound device 14 and the lamp support 26 is shown in FIGS. 4 and 5. The lamp support 26 acts as the amplifier 16, and amplifies the sound produced by the digital sound device 14. The component which serves as the amplifier is not limited to the vehicle components such as the upper cross-member 22 and the lamp support 26 as previously described; other components of the vehicle could be used as well.

Another feature of the present invention is that the digital audio horn device 10 of the present invention also has the ability to be tuned to produce a specific type of sound. The horn device 10 could be attached to a vehicle as shown in any of the figures, and the portion of the vehicle the horn is attached to, or the entire vehicle itself, could be placed into an anechoic chamber (also known as a “quiet chamber”). Various signals can be sent to the digital sound device 14, where the digital sound device can then covert the digital audio signal to an analog wave, where the amplifier 16 will amplify the sound. As the digital audio signal is varied, the sound produced by the amplifier 16 will vary as well. Once the appropriate digital audio signal is sent to the amplifier 16 to produce the desired note, the appropriate signal can then be saved into the control module such that each time the horn device 10 is used, the desired sound is achieved.

Also, if other sounds are desired for different purposes, the control module can be programmed to store other various digital audio signals for producing other various desired sounds. Certain vehicles also have touchscreens which allow the user to control various operating parameters of the vehicle, such as heating and air conditioning. These touchscreens could also be programmed to allow the user to control the control module to cause the horn device 10 to produce other various sounds as well.

The present invention solves of the problems associated with a conventional horn because a digital signal is used to create the desired note, not specific hardware. The invention does not require the use of a trumpet, so it is not susceptible to water accumulation. Additionally, the invention does not require that all the conditions regarding the location and mounting bracket exist in order to function as desired. The digital signal can be adjusted based on the mounting conditions on a given vehicle to achieve a desired output signal. The note can be adjusted by simply changing the digital audio signal on the control module or data storage device. A clear sound can still be produced regardless of location (under hood or between components), using the invention. It is the ability to alter the digital signal that allows for common hardware and a variety of environments, without imposing additional design limitations. Another feature of the present invention is the invention can use various planes of the vehicle for manipulation of the sound. For example, the fender or hood of the vehicle can be used as an amplifier to increase the output of the present invention, thereby producing the desired sound.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A device for producing sound amplification, comprising:
a control module operably associated with a digital sound device;
an amplifier connected to and supporting said digital sound device; and
said control module provides at least one input signal to said digital sound device, and said digital sound device receives an input signal from said control module, causing said digital sound device to produce a vibration, causing said amplifier to increase the magnitude of said vibration.

2. The device for producing sound amplification of claim 1, said amplifier further comprising at least one component of a motor vehicle.

3. The device for producing sound amplification of claim 1, said control module further comprising a totally integrated power module for producing a control signal to said digital sound device, and for providing electrical power to said digital sound device.

4. The device for producing sound amplification of claim 3, where said totally integrated power module changes said at least one input signal delivered to said digital sound device, thereby changing the vibration produced by said digital sound device and said amplifier.

5. The device for producing sound amplification of claim 1, said at least one input signal further comprising a series of input signals, each of said series of input signals being different from one another.

6. The device for producing sound amplification of claim 5, wherein said series of input signals are used to produce a series of sounds from said amplifier.

7. The device for producing sound amplification of claim 1, said digital sound device further comprising a digital to analog converter.

8. The device for producing sound amplification of claim 1, said digital sound device further comprising a power supply independent of said control module, and said control module is not directly connected to said digital sound device.

9. A digital audio horn, comprising:
a power module connected to a digital to analog converter;
an amplifier supporting and connected to said digital to analog converter; and
when said power module provides a digital audio signal to said digital to analog converter through said digital power feed, said digital to analog converter will convert said digital audio signal to an analog wave, and said amplifier will amplify said analog wave to produce a desired note.

10. The digital audio horn of claim 9, said power module connected to said digital to analog converter through the use of a power feed.

11. The digital audio horn of claim 9, wherein said amplifier is a component of a motor vehicle.

12. The digital audio horn of claim 11, wherein said component of said motor vehicle is one selected from the group consisting of a hood, a fender, an upper cross-member, a lamp support, and a bumper.

13. The digital audio horn of claim 9, said power module further comprising a totally integrated power module for providing said desired digital audio signal to said digital to analog converter, and for providing electrical power to said digital to analog converter.

14. The digital audio horn of claim 3, wherein said power module also provides power output to said digital sound device, and said amplifier.

15. A method for tuning a digital horn, comprising the steps of:
providing a control module operably associated with a digital sound device;
providing an amplifier connected to said digital sound device;
placing said amplifier and said digital sound device into an anechoic chamber;
sending a control signal from said control module to said digital sound device, causing said digital sound device to generate a vibration;
amplifying said vibration of said digital sound device with said amplifier;
varying said control signal sent to said digital sound device to achieve a desired vibration produced by said amplifier.

16. The method for tuning a digital horn of claim 15, further comprising the steps of said amplifier to be comprised of at least one component of an automobile.

17. The method for tuning a digital horn of claim 15, further comprising the steps of:
providing said digital sound device to be comprised of a digital to analog converter;
providing said control signal to be comprising of a digital signal;
sending said digital signal to said digital to analog converter;
converting said digital signal to an analog wave with said digital to analog converter; and
amplifying said analog wave with said amplifier.

18. The method for tuning a digital horn of claim 15, further comprising the steps of:
varying said control signal produced by said control module sent to said digital sound device until a desired sound is produced by said amplifier; and
programming said control module to send an appropriate control signal to said digital sound device to cause said amplifier to produce said desired sound.

19. The method for tuning a digital horn of claim 15, further comprising the steps of programming said control module to send other control signals to said digital sound device to cause said amplifier to produce other desired sounds.
